(19) United States
(12) Patent Application Publication
(10) Pub. No.: US 2013/0104801 A1
(43) Pub. Date: May 2, 2013

(54) MASK FOR USE IN EVAPORATION COATING DEVICE

(71) Applicant: SHAO-KAI PEI, Tu-Cheng (TW)

(72) Inventor: SHAO-KAI PEI, Tu-Cheng (TW)

(73) Assignee: HON HAI PRECISION INDUSTRY CO., LTD., Tu-Cheng (TW)

(21) Appl. No.: 13/420,551

(22) Filed: Mar. 14, 2012

(30) Foreign Application Priority Data
Oct. 31, 2011 (TW) 100139547

(51) Int. Cl. C23C 16/04

(52) U.S. Cl. 118/720; 118/504

(57) ABSTRACT

An evaporation coating device includes a hollow main portion, a loading rack, a source material, and a mask. The loading rack is received in the main portion and mounted on a top plate of the main portion for carrying workpieces to be coated. The source material for evaporation is arranged on a bottom plate of the main portion. The mask is positioned between the loading rack and the source material and includes a mounting rod, two masking plates rotatably mounted on the mounting rod and an adjusting element engaged with the mounting rod and positioned between the two masking plates. The masking plates cooperatively constitute a masking surface and the two masking plates can be rotated by the adjusting element to change the shape of a contour of the masking surface.

### BACKGROUND

1. Technical Field

The present disclosure relates to evaporation coating devices and, particularly, to a mask for use in an evaporation coating device.

2. Description of Related Art

Evaporation coating devices usually include a source material and an umbrella-shaped rack on which workpieces can be loaded. The rack is set above the source material. In the evaporation coating processes, the workpieces near the source material may capture more evaporant than those far from the source material thus evaporant near the source material will be thicker than that far from the source material. As a result, coating uniformity is not achieved. To solve the problem, a mask is employed to shield a part of the workpieces near the source material while not shielding the more distant parts, to increase the coating uniformity. However, the shape of the mask is usually fixed and cannot be changed when coating requirements are changed.

Therefore, it is desired to provide a mask for use in an evaporative coating device, which can overcome the above-mentioned problem.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a cross-sectional, schematic view of a coating device according to a first embodiment.

FIG. 2 is an isometric, exploded, schematic view of a mask of FIG. 1.

FIG. 3 is an isometric, assembled, schematic view of the mask of FIG. 2.

FIG. 4 is a planar schematic view of the mask of FIG. 3 in a first stage.

FIG. 5 is a planar schematic view of the mask of FIG. 3 in a second stage.

FIG. 6 is an isometric, assembled, schematic view of a mask, according to a second embodiment.

FIG. 7 is a planar schematic view of the mask device of FIG. 6.

### DETAILED DESCRIPTION

Embodiments of the present disclosure will be described with reference to the drawings.

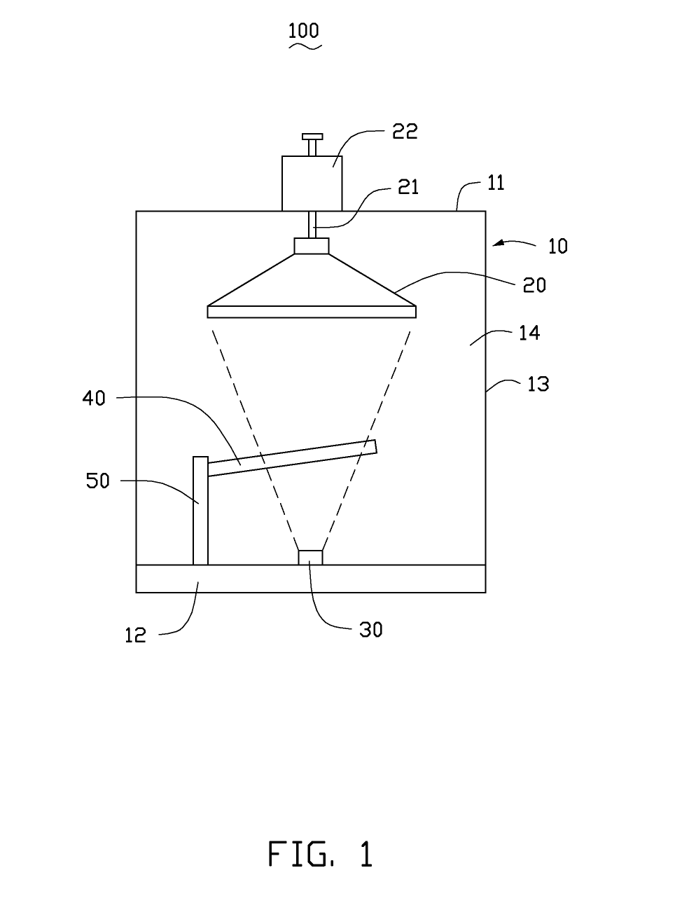

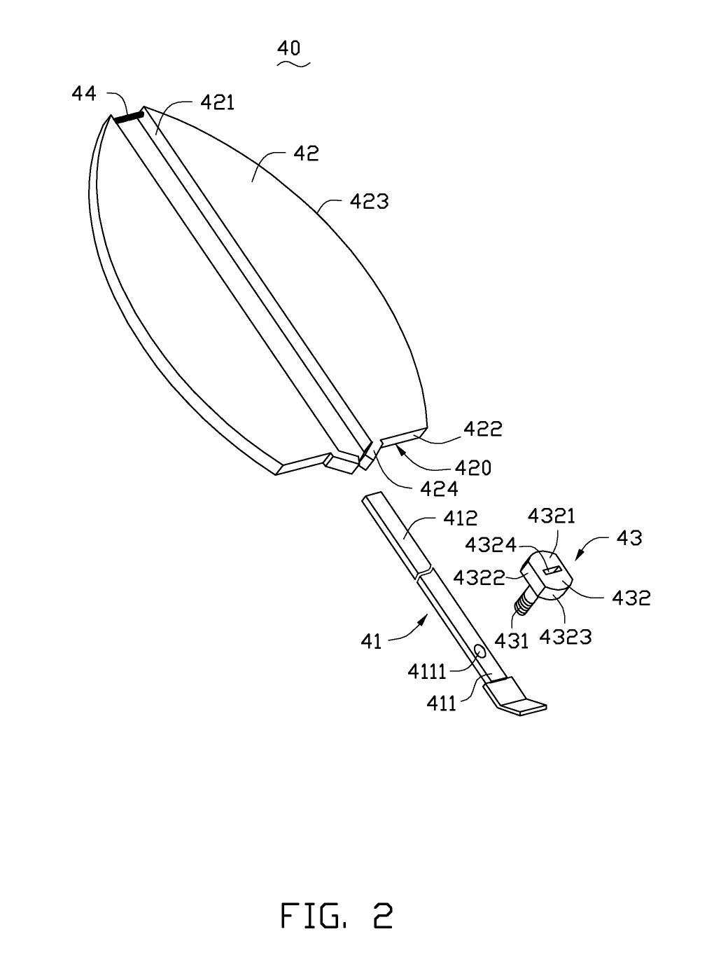

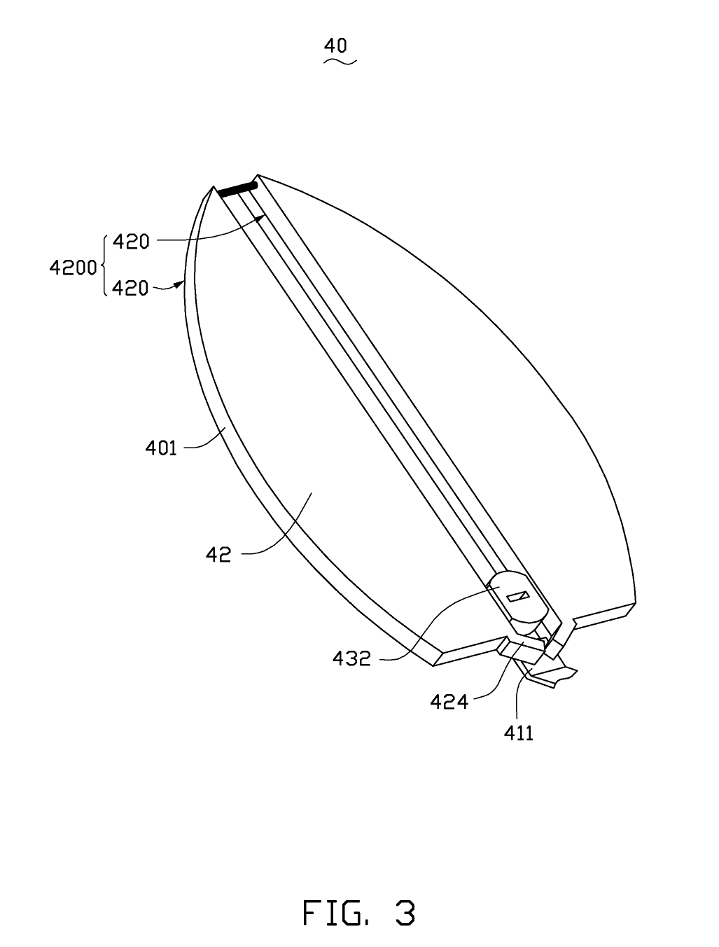

Referring to FIGS. 1-3, an evaporation coating device 100, according to a first embodiment, includes a main portion 10, a loading rack 20, a source material 30, and a mask 40.

The main portion 10 is a substantially hollow cylinder and includes a top plate 11, a bottom plate 12, and a cylindrical sidewall 13 perpendicularly connected between the top plate 11 and the bottom plate 12. The top plate 11, the bottom plate 12, and the sidewall 13 cooperatively define a chamber 14.

The loading rack 20 resembles an umbrella which is received in the chamber 14 and is used to carry workpieces (not shown) to be coated. The loading rack 20 is connected to a rotation shaft 21 and suspended from the top plate 11 with the rotation shaft 21 penetrating through the top plate 11. The rotation shaft 21 is further engaged with a driving motor 22 mounted on the exterior surface of the top plate 11. The driving motor 22 can rotate the rotation shaft 21 and thus turn the loading rack 20.

The source material 30 is received in the chamber 14 and arranged on the bottom plate 12. The source material 30 includes materials to be evaporated and deposited on the workpieces. The source material 30 can be heated and transforms to a gaseous state from a solid state by resistance heating manner or by electrons from an electron beam gun, which electrons are deflected by a magnetic field to hit the source material 30.

The mask 40 is received in the chamber 14 and positioned between and the loading rack 20 and the source material 30. The mask 40 is fixed to a holding rod 50 which is mounted on the bottom plate 12. The mask 40 is above the source material 30 and includes a mounting rod 41, two masking plates 42, an adjusting element 43, and an elastic element 44.

The mounting rod 41 is a long metallic strip. The mounting rod 41 includes a first end 411 and a second end 412 away from the first end 411. The mounting rod 41 defines a screw hole 4111 adjacent to the first end 411. In this embodiment, the screw hole 4111 is a blind hole.

The masking plates 42 are metallic or made of metal. Each of the masking plates 42 is generally a half-ellipse and includes a sub-masking surface 420, a first side surface 421 perpendicular to the sub-masking surface 420, a second side surface 422, and a third side surface 423. The sub-masking surface 420 faces the source material 30. The first side surface 421 and the second side surface 422 are straight and flat. The second side surface 422 is connected between the first side surface 421 and the third side surface 423. The third side surface 423 is parabolic surface convex away from the first side surface 421. Each masking plate 42 further includes an elastic arm 424 extending from a joint between the first side surface 421 and the second side surface 422.

The adjusting element 43 is a screw bolt and includes a threaded portion 431 and a head portion 432 connected to the threaded portion 431. The threaded portion 431 corresponds to the screw hole 4111. The head portion 432 resembles an athletics track in plan view and functions as a double-sided lobe or cam. The head portion 432 includes an operation surface 4321, a pair of first contact surfaces 4322, and a pair of second contact surfaces 4323. The operation surface 4321 is away from and perpendicular to the threaded portion 431. The operation surface 4321 defines a groove 4324 for the tip of a screwdriver (not shown). The first contact surfaces 4322 are perpendicular to the operation surface 4321 and parallel to each other. The second contact surfaces 4323 are connected between the first contact surfaces 4322 and bulge out. The straight-line distance between the second contact surfaces 4323 is greater than that between the first contact surfaces 4322.

The elastic element 44 is a coil spring.

When assembling, the thread portion 431 is screwed into and engages with the screw hole 4111 thus the adjusting element 43 is mounted to the mounting rod 41. The elastic arm 424 of each masking plate 42 is welded to the first end 411. The two masking plates 42 are symmetrically arranged about the mounting rod 41. The two sub-masking surfaces 420 of the two masking plates are coplanar and cooperatively constitute a masking surface 4200 which is adjustable. A contour 401 of the masking surface 4200 can be changed when the two masking plates 42 are rotated towards or away from each other. The two first side surfaces 421 of the two masking plates 42 face each other. The adjusting element 43 is rotatably positioned between the first side surfaces 421 with the operation surface 4321 substantially perpendicular to the first side surfaces 421. The elastic element 44 is connected between the two masking plates to constantly pull them together. Then the first end 411 is fixed to the holding rod 50.

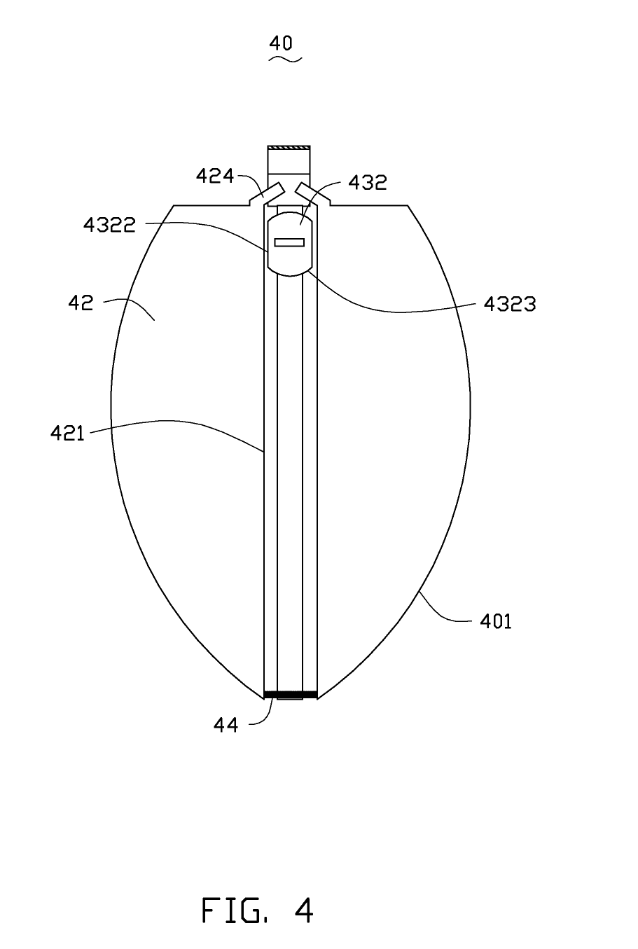

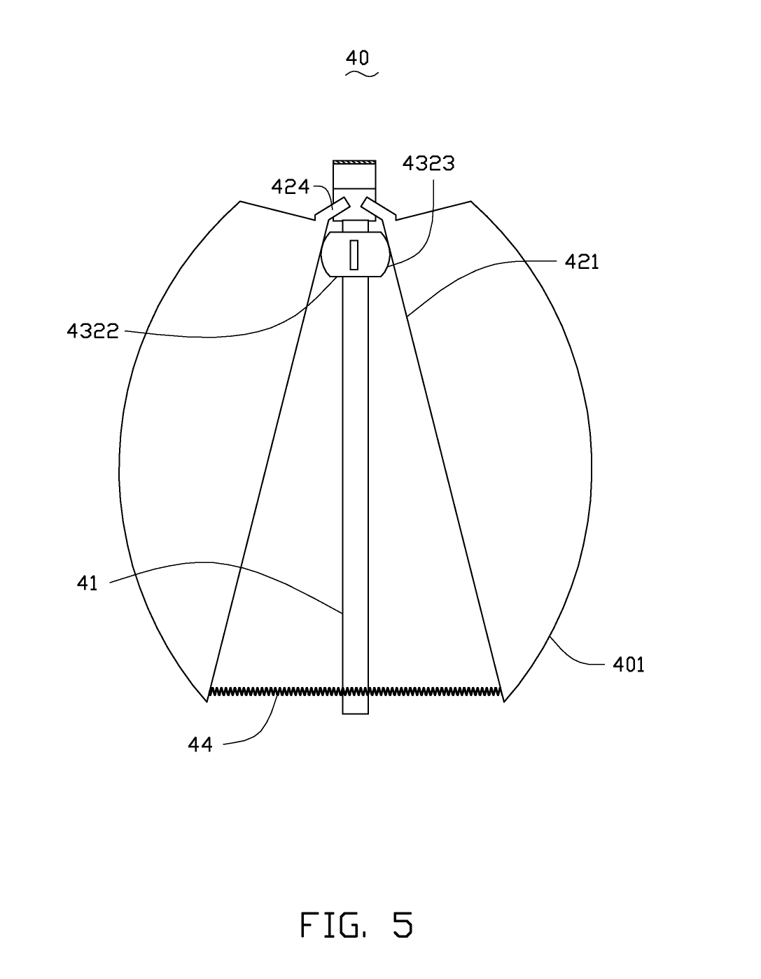

Referring to FIGS. 4 and 5, in use, the adjusting element 43 is rotated by means of the screwdriver, when each first contact surface 4322 is abutting a first side surface 421, the two first side surfaces 421 are parallel to each other, the two elastic arms 424 and the elastic element 44 are all in a resting and unstressed state. When each second contact surface 4323 bears on a first side surface 421, each masking plate 42 is forced to rotate about the elastic arm 424 by means of the action of the adjusting element 43. Therefore, the contour 401 of the masking surface 4200 is changed (FIG. 5 relates to FIG. 4). The two elastic arms 424 and the elastic element 44 deform accordingly. The elastic element 44 provides a pulling force to the two masking plates 42 to steadily maintain the contour 401 in whatever pattern is required until the adjusting element 43 is again rotated. In evaporation coating process, the masking surface 4200 cooperatively instituted by the two masking plates 42 can be changed thus the contour 401 of the masking surface 4200 is changable when coating requirements are changed.

In alterative embodiment, each of the masking plates 42 can be rectangular, circular, elliptical or other shapes. The elastic element 44 is not fundamental in the disclosure.

In alterative embodiments, the elastic arm 424 of each masking plate 42 can be mounted to the first end 411 by a screw passing through corresponding through holes of elastic arm 424 and the first end 411. The elastic arm 424 of each masking plate 42 can be omitted and each masking plate 42 can be mounted and affixed to the first end 411 by a screw.

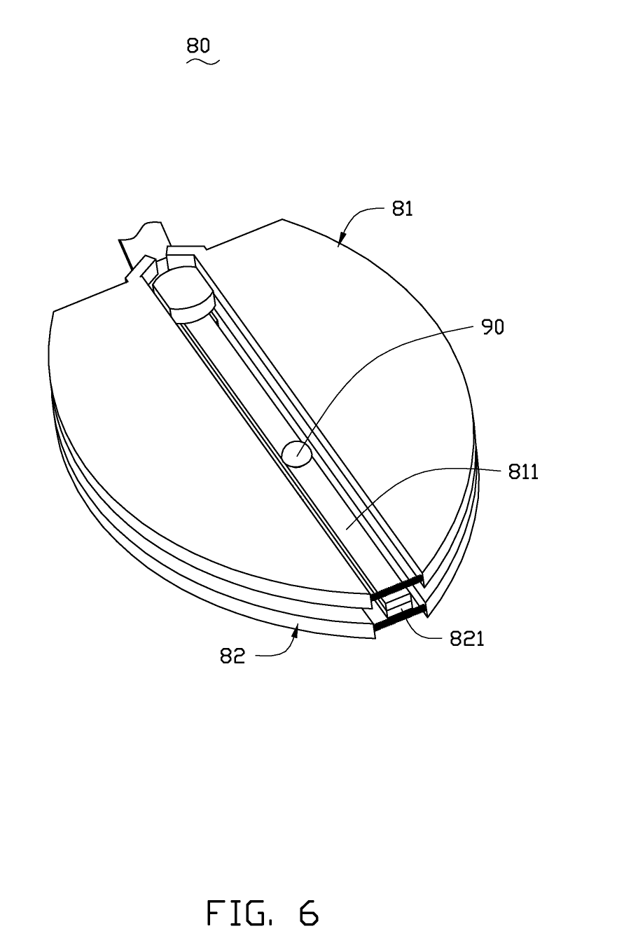

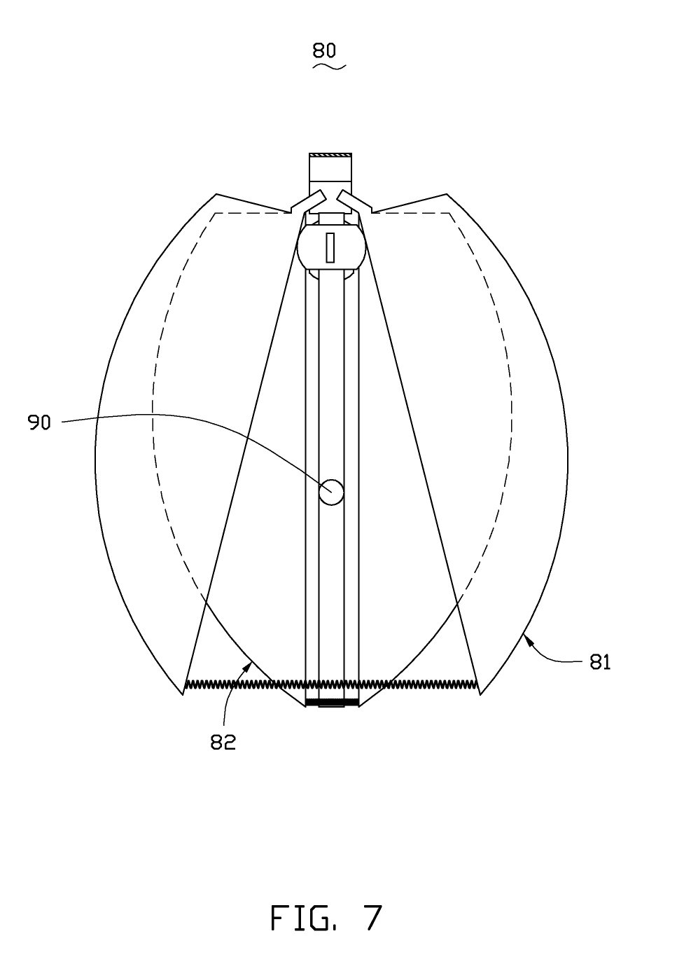

Referring to FIGS. 6 and 7, a mask 80 according to a second embodiment, includes a first sub-mask 81 and a second sub-mask 82.

The first sub-mask 81 and the second sub-mask 82 are both similar to the mask 40 of the first embodiment, except that the first sub-mask 81 includes a first mounting rod 811 defining a through hole (not shown) generally in the middle thereof and the second sub-mask 82 includes a second mounting rod 821 also defining a through hole (not shown) corresponding to the through hole of the first mounting rod 811.

The first sub-mask 81 is stacked on the second sub-mask 82 and connected to the second sub-mask 82 by a screw 90 passing through the corresponding through holes of the first mounting rod 811 and the second mounting rod 821. In this embodiment, the first sub-mask 81 and the second mask 82 can form different shapes to satisfy different coating requirements.

In alterative embodiment, the first sub-mask 81 and the second sub-mask 82 are identical with the mask 40 of the first embodiment, the first mounting rod 811 and the seconding mounting rod 821 are connected by welding.

It will be understood that the above particular embodiments are shown and described by way of illustration only. The principles and the features of the present disclosure may be employed in various and numerous embodiment thereof without departing from the scope of the disclosure as claimed. The above-described embodiments illustrate the possible scope of the disclosure but do not restrict the scope of the disclosure.

What is claimed is:

1. A mask, comprising:
a mounting rod;
two masking plates rotatably mounted on the mounting rod, the masking plates cooperatively constituting a masking surface; and
an adjusting element engaged with the mounting rod and positioned between the two masking plates;
wherein the adjusting element is configured for driving the two masking plates to rotate, so as to change the shape of a contour of the masking surface.

2. The mask of claim 1, wherein the mounting rod comprises a first end and a second end away from the first end, the masking plates are mounted on the first end.

3. The mask of claim 2, wherein the mounting rod defines a screw hole adjacent to the first end, the adjusting element is a screw bolt and comprises a threaded portion and a cam shaped head portion, the threaded portion engages with the screw hole and the head portion abuts the masking plates for driving the two masking plates to rotate.

4. The mask of claim 3, wherein the mounting rod and the masking plates are made of metal, each of the masking plates comprises an elastic arm; the elastic arm is welded to the first end.

5. The mask of claim 4, wherein each masking plate comprises a sub-masking surface, a first side surface perpendicular to the sub-masking surface; two sub-masking surfaces of the two masking plates cooperatively institute the masking surface, the first side surface is flat, two first side surfaces of the two masking plates face each other; the head portion comprises a pair of first contact surfaces and a pair of second contact surfaces; the straight-line distance between the second contact surfaces is greater than that between the first contact surfaces; when each first contact surface abutting on a corresponding first side surface, the first side surfaces are parallel to each other, the two elastic arms are in a resting and unstressed state.

6. The mask device of claim 5, wherein the mask further comprises an elastic element connected between the two masking plates; when each second contact surface bearing on a corresponding first side surface, each masking plate is forced to rotate about the elastic arm by the adjusting element, the two elastic arms and the elastic element deform, the elastic element provides a pulling force to the two masking plates.

7. The mask of claim 5, wherein each masking plate further comprises a second side surface, and a third side surface; the second side surface is connected between the first side surface and the third side surface, the third side surface is a parabolic surface convex away from the first side surface; the elastic arm extends from a joint between the first side surface and the second side surface.

8. The mask of claim 5, wherein the head portion further comprises an operation surface perpendicular to the first contact surface and the threaded portion; the operation surface defines a groove.

9. The mask of claim 1, wherein the two masking plates are coplanar with each other.

10. A mask, comprising:
a first sub-mask and a second sub-mask; each of the first sub-mask and the sub-mask comprising:
a mounting rod;
two masking plates rotatably mounted on the mounting rod, the masking plates cooperatively constituting a masking surface; and
an adjusting element engaged with the mounting rod and positioned between the two masking plates; wherein the adjusting element is configured for driving the two masking plates to rotate, so as to change the shape of a contour of the masking surface;
wherein the first sub-mask is stacked on the second sub-mask with two mounting rods being connected together.

11. The mask of claim 10, wherein the two mounting rods are connected together by welding.

12. An evaporation coating device, comprise:
a hollow main portion;
a loading rack received in the main portion and mounted on a top plate of the main portion for loading workpieces to be coated;
a source material arranged on a bottom plate of the main portion to be evaporated; and
a mask positioned between the loading rack and the source material, the mask comprising:
a mounting rod;
two masking plates rotatably mounted on the mounting rod, the masking plates cooperatively constituting a masking surface; and
an adjusting element engaged with the mounting rod and positioned between the two masking plates;
wherein the adjusting element is configured for driving the two masking plates to rotate, so as to change the shape of a contour of the masking surface.

13. The evaporation coating device of claim 12, wherein the mounting rod comprises a first end and second end away from the first end, the masking plates are mounted on the first end; the mounting rod defines a screw hole adjacent to the first end, the adjusting element is a screw bolt comprising a threaded portion and a cam shaped head portion, the threaded portion engages with the screw hole and the head portion abuts the masking plates for driving the two masking plates to rotate.

14. The evaporation coating device of claim 13, wherein the mounting rod and the masking plates are made of metal, each of the masking plates comprises an elastic arm; the elastic arm is welded to the first end.

15. The evaporation coating device of claim 14, wherein each masking plate comprises a sub-masking surface, a first side surface perpendicular to the sub-masking surface; two sub-masking surfaces of the two masking plates cooperatively institute the masking surface, the first side surface is flat, two first side surfaces of the two masking plates face each other; the head portion comprise a pair of first contact surfaces and a pair of second contact surfaces; the straight-line distance between the second contact surfaces is greater than that between the first contact surfaces; when each first contact surface abutting a corresponding first side surface, the two first side surfaces are parallel to each other, the two elastic arms are in a resting and unstressed state.

16. The evaporation coating device of claim 15, wherein the mask further comprises an elastic element connected between the two masking plates; when each second contact surface bearing on a corresponding first side surface, each masking plate is forced to rotate about the elastic arm by the adjusting element, the two elastic arms and the elastic element deform, the elastic element provides a pulling force to the two masking plates.

17. The evaporation coating device of claim 15, wherein each masking plate further comprises a second side surface, and a third side surface; the second side surface is connected between the first side surface and the third side surface, the third side surface is a parabolic surface convex away from the first side surface, the elastic arm extends from a joint between the first side surface and the second side surface.
